(19) United States
(12) Patent Application Publication
(10) Pub. No.: US 2025/0329648 A1
(43) Pub. Date: Oct. 23, 2025

(54) CONDUCTIVE PASTE VSS SHORTING FOR GROUND BUMPS

(71) Applicant: QUALCOMM Incorporated, San Diego, CA (US)

(72) Inventors: Aniket PATIL, San Diego, CA (US); Yujen CHEN, Taichung (TW); Zhijie WANG, San Diego, CA (US)

(21) Appl. No.: 18/638,329

(22) Filed: Apr. 17, 2024

(51) Int. Cl. H01L 23/528; H01L 21/48; H01L 23/00; H01L 23/498

(52) U.S. Cl. CPC H01L 23/5286; H01L 21/486; H01L 21/4867; H01L 23/49816; H01L 24/13; H01L 24/29; H01L 24/73; H01L 2224/13009; H01L 2224/13025; H01L 2224/29005; H01L 2224/29021; H01L 2224/73153; H01L 2924/15311; H01L 2924/182

(57) ABSTRACT

In an aspect, an integrated circuit (IC) device includes a substrate having a non-conductive film disposed on a first surface, a die having a plurality of pins including VSS pins and non-VSS pins having an insulating layer, wherein the plurality of pins is coupled to the substrate through the non-conductive film, and a conductive underfill disposed between the die and the substrate, wherein the conductive underfill is coupled to the VSS pins.

### BACKGROUND OF THE DISCLOSURE

### 1. Field of the Disclosure

Aspects of the disclosure generally relates to an integrated circuit (IC) package, and more particularly, to an IC package that includes VSS pins and non-VSS pins.

### 2. Description of the Related Art

IC technology has achieved great strides in advancing computing power through miniaturization of electronic components. An IC chip or an IC die may include a set of circuits integrated thereon. In some implementations, an IC device may be formed by incorporating and protecting one or more IC chips or dies in an IC package, where various power and signal nodes of the one or more IC chips can be electrically coupled to respective conductive terminals of the IC package via electrical paths formed in one or more package substrates of the IC package. The term “substrate” in this disclosure, unless otherwise specified, refers to a packaging substrate for packaging one or more IC chips, which is different from the semiconductor substrate for forming an IC chip.

Various packaging technologies can be found in many electronic devices, including processors, servers, mobile devices, radio frequency (RF) ICs, etc. Advanced packaging and processing techniques allow for complex devices, such as multi-die devices and system-on-a-chip (SOC) devices, which may include multiple function blocks, with each function block designed to perform a specific function, such as, for example, a microprocessor function, a graphics processing unit (GPU) function, a communications function (e.g., cellular, Wi-Fi, Bluetooth, and/or other communications), and the like.

In mobile devices, such as phones or smart watches, the sizes of ICs may be severely constrained. For example, both the surface area and the height of an IC in a mobile device may be severely limited by the overall size of the mobile device. Meanwhile, ICs may be increasingly required to possess ever greater computational capacity and perform an ever greater number of functions, for example, various communication functions according to various communication protocols (e.g., 4G, 5G, Wi-Fi, Bluetooth, and/or other protocols), in mobile devices. Consequently, there may be increasingly tighter requirements for pin density in IC devices.

In some examples, an IC die with a plurality of pins may be mounted on a package substrate. The pins may provide electrical connections between the substrate and circuit components within the IC die. In some examples, the pins may include power supply pins such as VSS and/or VDD pins in a power delivery network (PDN) as well as input/output (I/O) pins. In an IC package for mobile applications, for example, various VSS/VDD pins and I/O pins may be densely positioned relative to each other due to the physical constraints on the size of the IC package. In some examples, there may be a challenge to configure pin structures to ensure proper impedance of high-speed I/O return paths in order to maintain an optimal level of system performance.

Accordingly, there is a need for improved structures for an IC package and methods of manufacturing the same to address the above-noted issues.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a device includes a substrate having a non-conductive film disposed on a first surface; a die having a plurality of pins including VSS pins and non-VSS pins having an insulating layer, wherein the plurality of pins are coupled to the substrate through the non-conductive film; and a conductive underfill disposed between the die and the substrate, wherein the conductive underfill is coupled to the VSS pins.

In an aspect, a method of making a device includes forming a plurality of pins on a die including VSS pins and non-VSS pins; depositing an insulating layer on the non-VSS pins; depositing a non-conductive film on a substrate; coupling the die to the substrate; and depositing a conductive underfill on the non-conductive film between the substrate and the die and coupling the conductive underfill to the VSS pins.

In an aspect, an electronic device includes an integrated circuit (IC) package that comprises: a substrate having a non-conductive film disposed on a first surface; a die having a plurality of pins including VSS pins and non-VSS pins having an insulating layer, wherein the plurality of pins are coupled to the substrate through the non-conductive film; and a conductive underfill disposed between the die and the substrate, wherein the conductive underfill is coupled to the VSS pins.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 is a cross-sectional view of an IC package, according to aspects of the disclosure.

FIGS. 2A-2D illustrate structures at various stages of manufacturing an IC package, according to aspects of the disclosure.

FIGS. 3A-3E illustrate structures at various stages of manufacturing an IC package, according to aspects of the disclosure.

FIG. 4 illustrates a method 400 for manufacturing an IC package, according to aspects of the disclosure.

FIG. 5 is a cross-sectional view of an IC package, according to aspects of the disclosure.

FIG. 6 illustrates a method for manufacturing an IC package, according to aspects of the disclosure.

FIG. 7 illustrates a mobile device, according to aspects of the disclosure.

FIG. 8 illustrates various electronic devices that may incorporate IC devices being put into the IC packages described herein, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

In certain described example implementations, instances are identified where various component structures and portions of operations can be taken from known, conventional techniques, and then arranged in accordance with one or more aspects. In such instances, internal details of the known, conventional component structures and/or portions of operations may be omitted to help avoid potential obfuscation of the concepts illustrated in the illustrative aspects disclosed herein.

The terminology used herein is for the purpose of describing particular aspects only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. Additionally, terms such as approximately, generally, and the like indicate that the examples provided are not intended to be limited to the precise numerical values or geometric shapes and include normal variations due to, manufacturing tolerances and variations, material variations, and other design considerations.

As noted in the foregoing, various aspects relate generally to an integrated circuit (IC) package that includes a conductive underfill disposed between a package substrate and an IC die which has a plurality of pins including VSS pins and non-VSS pins, wherein the conductive underfill is coupled to the VSS pins. In some aspects, the non-VSS pins have an insulating layer. In some aspects, the substrate has a non-conductive film disposed on a first surface. In some aspects, the plurality of pins are coupled to the substrate through the non-conductive film. In some aspects, the non-conductive film is separated from the die by a gap. In some aspects, the gap between the non-conductive film and the die is occupied by the conductive underfill. In some aspects, the conductive underfill comprises a conductive paste. In some aspects, the insulating layer is disposed between the non-VSS pins and the conductive underfill. In some aspects, the insulating layer comprises silicon dioxide (SiO₂). In some aspects, the substrate comprises a VSS plane configured to operate at a ground or negative potential. In some aspects, the substrate comprises a VDD plane configured to operate at a potential greater than the VSS plane.

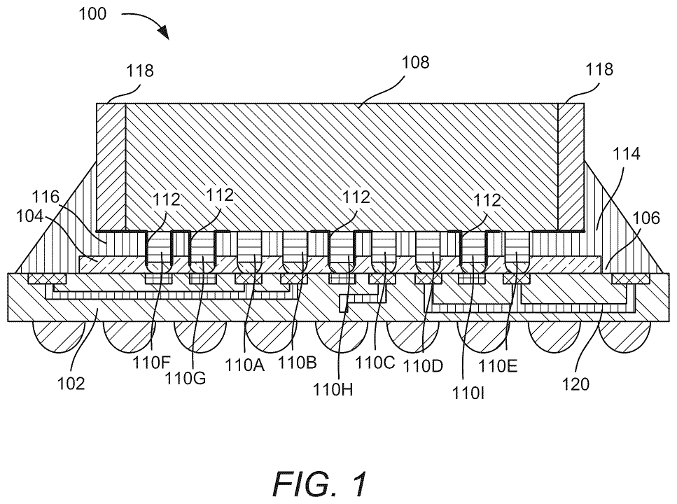

FIG. 1 is a cross-sectional view of an IC package 100, according to aspects of the disclosure. In some aspects, FIG. 1 is a simplified cross-sectional view of the IC package 100, and certain details and components of the IC package 100 may be simplified or omitted in FIG. 1.

In some aspects, as shown in FIG. 1, the IC package 100 may include a substrate 102 having a non-conductive film 104 disposed on a first surface 106. In some aspects, the IC package 100 may include a die 108 having a plurality of pins 110A, 110B, 110C, 110D, 110E, 110F, 110G, 110H and 110I including VSS pins 110A, 110B, 110C, 110D and 110E and non-VSS pins 110F, 110G, 110H and 110I. In some aspects, among these pins, the non-VSS pins 110F, 110G, 110H and 110I have an insulating layer 112. In some aspects, the plurality of pins 110A, 110B, 110C, 110D, 110E, 110F, 110G, 110H and 110I are coupled to the substrate 102 through the non-conductive film 104.

In some aspects, a conductive underfill 114 is disposed between the die 108 and the substrate 102. In some aspects, the conductive underfill 114 is coupled to the VSS pins 110A, 110B, 110C, 110D and 110E. In some aspects, the conductive underfill 114 allows the VSS pins 110A, 110B, 110C, 110D and 110E to have robust electrical connections with a VSS source.

In some aspects, the non-conductive film 104 and the insulating layer 112 prevent the VSS from forming electrical contacts with the non-VSS pins 110F, 110G, 110H and 110I. In some aspects, the non-VSS pins may include, for example, input/output (I/O) pins for inputting/outputting digital data, analog signals, RF signals, or the like.

In some aspects, the non-conductive film 104 may be separated from the die 108 by a gap 116. In some aspects, the gap 116 between the non-conductive film 104 and the die 108 may be occupied by the conductive underfill 114.

In the example shown in FIG. 1, a molding 118 may be provided on the sidewalls of the die 108. In an aspect, the conductive underfill 114 may be disposed on at least a portion of the molding 118. In another aspect, the conductive underfill 114 may not need to be in contact with the molding 118. In an aspect, the conductive underfill 114 may comprise a conductive paste.

In an aspect, the insulating layer 112 may be disposed between the non-VSS pins 110F, 110G, 110H and 110I and the conductive underfill 114, to provide electrical insulation between the non-VSS pins 110F, 110G, 110H and 110I and the conductive underfill 114. In an aspect, the insulating layer 112 may comprise silicon dioxide (SiO₂). In various aspects, the insulating layer 112 may comprise another type of insulating material, such as silicon nitride (SiN), silicon dioxide (SiO₂), or another dielectric material.

In an aspect, the substrate 102 may comprise a VSS plane 120 which may be configured to operate at a ground or negative potential. In another aspect, the substrate 102 may comprise a VDD plane 104 which may be configured to operate at a ground or positive potential, and the pins 110A, 110B, 110C, 110D and 110E may serve as VDD pins in this example.

It will be appreciated that the illustrated configuration and descriptions provided herein are merely to aid in the explanation of the various aspects disclosed herein. Accordingly, the forgoing illustrative examples should not be construed to limit the various aspects disclosed and claimed herein.

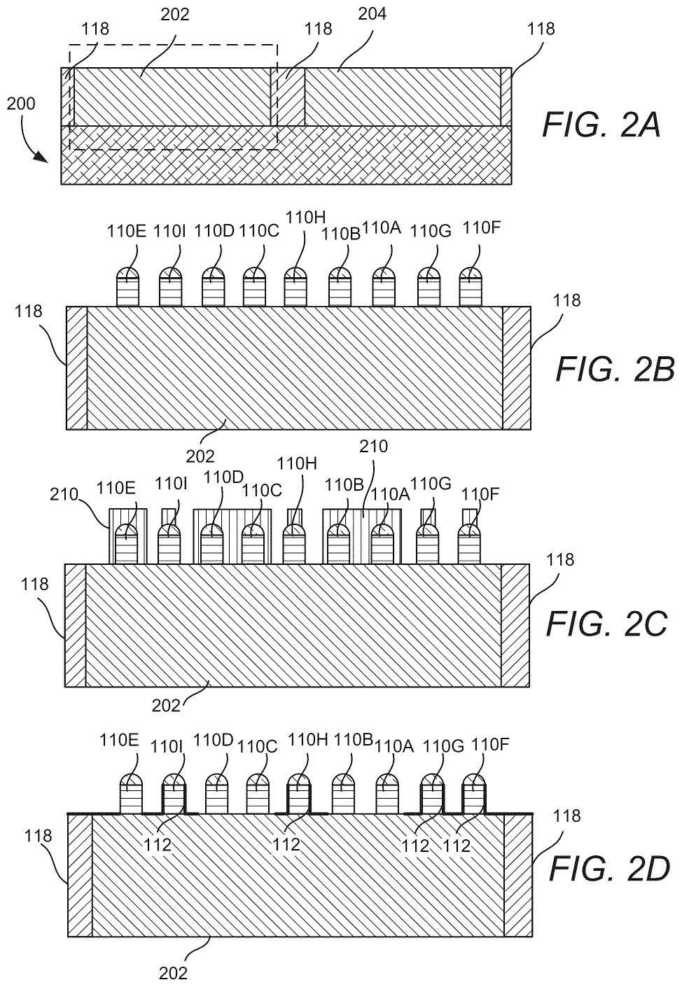

FIGS. 2A-2D illustrate structures at various stages of manufacturing an IC package, such as the IC package 100 in FIG. 1, according to aspects of the disclosure. The components illustrated in FIGS. 2A-2D that are the same or similar to those of FIG. 1 are given the same reference numbers, and the detailed description thereof may be omitted.

FIG. 2A illustrates a portion a wafer 200 in an example of a preparatory step for making an IC package 100 of FIG. 1, according to aspects of the disclosure. In FIG. 2A, the wafer 200 may include one or more dies, for example, dies 202 and 204. In some aspects, the wafer 200 may be reconstituted, and a molding 118 may be applied to the wafer 200 to provide sidewall insulation for the dies 202 and 204. Any one of the dies 202 and 204 may be used as the die 108 in the IC package 100 as illustrated in FIG. 1. In some aspects, wafer preparation may be performed in various manners according to aspects of the disclosure.

FIG. 2B illustrates a plurality of pins 110A, 110B, 110C, 110D, 110E, 110F, 110G, 110H and 110I formed on the die 202 by a standard bumping process. In some aspects, the pins 110A, 110B, 110C, 110D, 110E, 110F, 110G, 110H and 110I may be formed on the die 202 by another process according to aspects of the disclosure.

FIG. 2C illustrates a photo process which applies a photoresist 210 to cover the VSS pins 110A, 110B, 110C, 110D and 110E while exposing the non-VSS pins 110F, 110G, 110H and 110I on the die 202. In some aspects, the VSS pins 110A, 110B, 110C, 110D and 110E may be covered and the non-VSS pins 110F, 110G, 110H and 110I may be exposed in another process according to aspects of the disclosure.

FIG. 2D illustrates a process for depositing an insulating layer 112 on the sidewalls of the non-VSS pins 110F, 110G, 110H and 110I for insulation. In an aspect, the insulating layer 112 may be formed on the sidewalls of the non-VSS pins by a deposition process, for example, a molecular vapor deposition (MVD) process.

In an aspect, the insulating layer 112 may comprise silicon dioxide (SiO₂). In various aspects, other types of insulating materials may be applied to the non-VSS pins 110F, 110G, 110H and 110I as the insulating layer 112. In an aspect, after the insulating layer 112 is formed on the non-VSS pins 110F, 110G, 110H and 110I, the photoresist 210 (shown in FIG. 2C) may be stripped or removed.

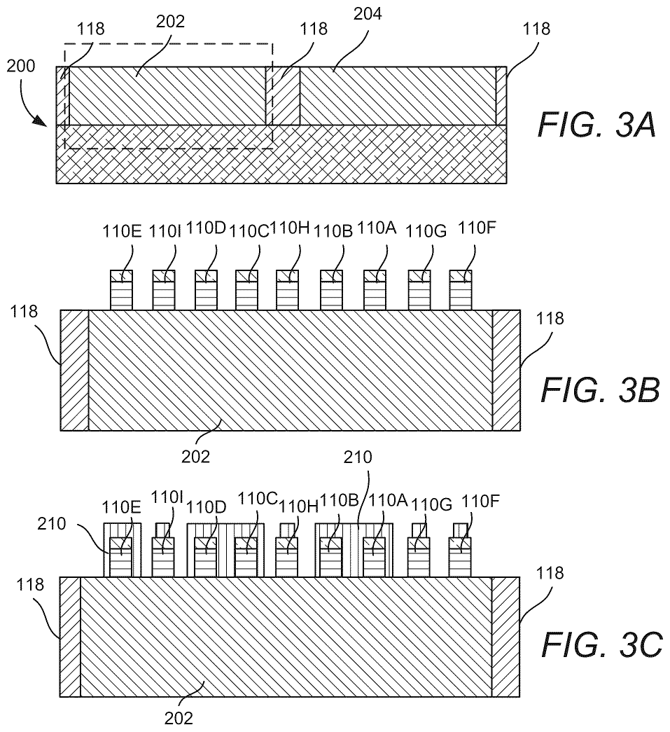

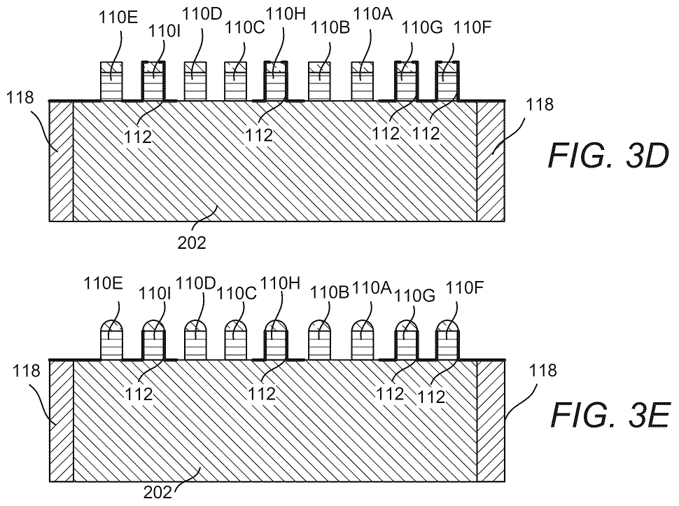

FIGS. 3A-3E illustrate structures at various stages of manufacturing an IC package, such as the IC package 100 in FIG. 1, according to aspects of the disclosure. The components illustrated in FIGS. 3A-3F that are the same or similar to those of FIGS. 1 and 2A-2D are given the same reference numbers, and the detailed description thereof may be omitted.

FIG. 3A illustrates a portion a wafer 200 in an example of a preparatory step for making an IC package 100 of FIG. 1, according to aspects of the disclosure. The process for preparing the wafer 200 may be the same as or similar to the process described with respect to FIG. 2A above. In an aspect, the wafer 200 may include one or more dies, for example, dies 202 and 204. In some aspects, the wafer 200 may be reconstituted, and a molding 118 may be applied to the wafer 200 to provide sidewall insulation for the dies 202 and 204. Any one of the dies 202 and 204 may be used as the die 108 in the IC package 100 as illustrated in FIG. 1. In some aspects, wafer preparation may be performed in various manners according to aspects of the disclosure.

FIG. 3B illustrates a plurality of pins 110A, 110B, 110C, 110D, 110E, 110F, 110G, 110H and 110I formed on the die 202 by a standard bumping process similar to the process described above with respect to FIG. 2B, except that FIG. 3B illustrates a standard bumping process before bump reflow. In some aspects, the pins 110A, 110B, 110C, 110D, 110E, 110F, 110G, 110H and 110I may be formed on the die 202 by another process according to aspects of the disclosure.

FIG. 3C illustrates a photo process which applies a photoresist 210 to cover the VSS pins 110A, 110B, 110C, 110D and 110E while exposing the non-VSS pins 110F, 110G, 110H and 110I on the die 202, similar to the process described above with respect to FIG. 2C. In some aspects, the VSS pins 110A, 110B, 110C, 110D and 110E may be covered and the non-VSS pins 110F, 110G, 110H and 110I may be exposed in another process according to aspects of the disclosure.

FIG. 3D illustrates a process for depositing an insulating layer 112 on the sidewalls of the non-VSS pins 110F, 110G, 110H and 110I for insulation, similar to the process described above with respect to FIG. 2D. In an aspect, the insulating layer 112 may be formed on the sidewalls of the non-VSS pins by a deposition process, for example, a molecular vapor deposition (MVD) process.

In an aspect, the insulating layer 112 may comprise silicon dioxide (SiO₂). In various aspects, other types of insulating materials may be applied to the non-VSS pins 110F, 110G, 110H and 110I as the insulating layer 112. In an aspect, after the insulating layer 112 is formed on the non-VSS pins 110F, 110G, 110H and 110I, the photoresist 210 (shown in FIG. 2C) may be stripped or removed.

FIG. 3E illustrates the pins 110A, 110B, 110C, 110D, 110E, 110F, 110G, 110H and 110I including the non-VSS pins 110F, 110G, 110H and 110I with the insulating layer 112 and the VSS pins 110A, 110B, 110C, 110D and 110E without the insulating layer 112 after a bump reflow process. In some aspects, the process described with respect to FIGS. 3A-3E may be used as an alternative to the process described with respect to FIGS. 2A-2D for manufacturing an IC package, such as IC package as shown in FIG. 1.

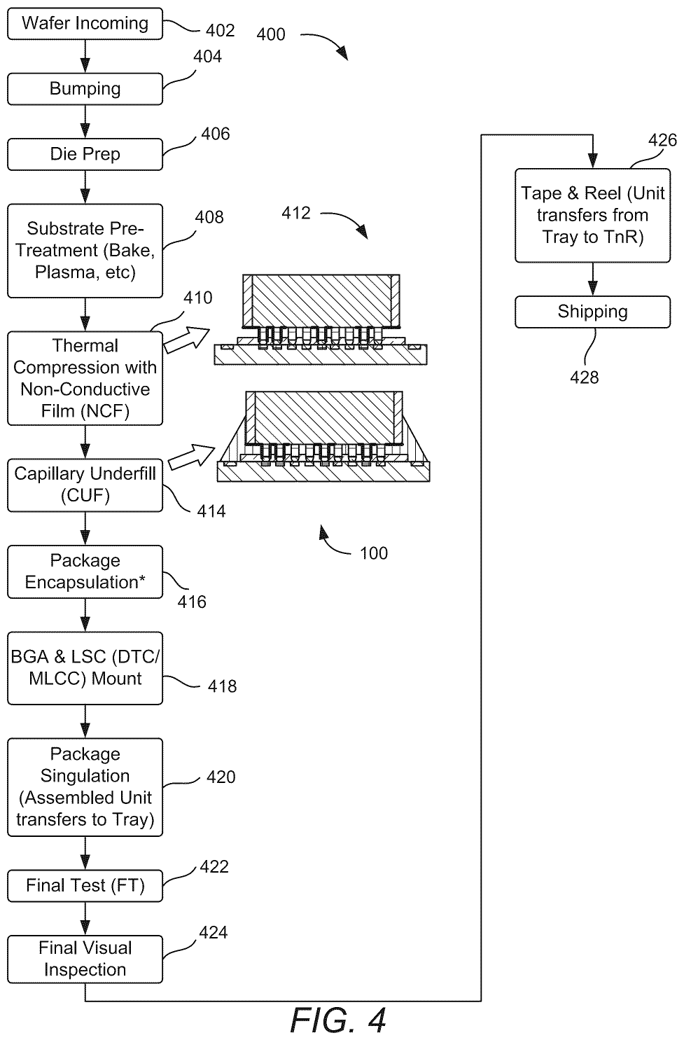

FIG. 4 illustrates a method 400 for manufacturing an IC package (such as the IC package 100 as shown in FIG. 1), according to aspects of the disclosure. In some aspects, FIGS. 2A-2D and FIGS. 3A-3E may depict portions of the IC package examples at different stages of manufacturing according to the method 400.

At operation 402, an incoming wafer (e.g., wafer 200) may be provided. At operation 404, a plurality of pins (e.g., pins 110A, 110B, 110C, 110D, 110E, 110F, 110G, 110H and 110I) may be formed on the wafer by a bumping process. At operation 406, one or more dies (e.g., die 108, 202, 204) may be prepared on the wafer. In some aspects, die preparation may include providing molding (e.g., molding 118) to provide sidewall insulation for the dies (e.g., dies 202 and 204).

At operation 408, a package substrate (e.g., substrate 102) may undergo pre-treatment, including, for example, baking, plasma treatment, and/or other processes. At operation 410, a non-conductive film (e.g., non-conductive film 104) may be formed on the package substrate (e.g., substrate 102) by a process including, for example, thermal compression. An example of an IC package after forming a non-conductive film but before a conductive underfill is applied is shown as IC package 412 in FIG. 4.

At operation 414, a conductive underfill (e.g., conductive underfill 114), is provided on the non-conductive film (e.g., non-conductive film 104) between the substrate (e.g., substrate 102) and the die (e.g., die 108, 202, 204). In an aspect, the conductive underfill (e.g., conductive underfill 114) is disposed to couple the conductive underfill (e.g., conductive underfill 114) to the VSS pins (e.g., VSS pins 110A, 110B, 110C, 110D and 110E). In an aspect, the conductive underfill may comprise a capillary underfill. An example of an IC package after the conductive underfill (e.g., conductive underfill 114) is formed is shown as IC package 100 in FIG. 4.

At operation 416, the IC package (e.g., IC package 100) may be encapsulated. At operation 418, a ball grid array (BGA) and/or LITE-ON Semiconductor (LSC) package mount may be applied to the IC package (e.g., IC package 100). In some aspects, package mount may be achieved by thermo-compression, mass reflow, laser assisted bonding, for example. At operation 420, package singulation may be applied to the IC package (e.g., IC package 100). At operation 422, a final test may be performed on the IC package (e.g., IC package 100). At operation 424, a final visual inspection may be performed on the IC package (e.g., IC package 100). At operation 426, shipping media such as tape and reel may be applied to finished chip packages. At operation 428, one or more IC packages (e.g., IC package 100) may be shipped.

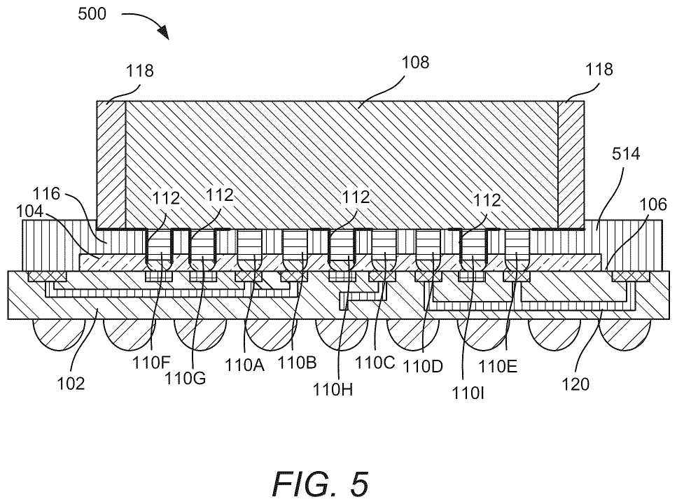

FIG. 5 is a cross-sectional view of an example IC package 500, according to aspects of the disclosure. The IC package 500 as shown in FIG. 5 is similar to the IC package 100 as shown in FIG. 1 and described above, except that conductive underfill 514, which is disposed between the die 108 and the substrate 102 and is coupled to the VSS pins 110A, 110B, 110C, 110D and 110E, is not disposed over a substantial portion of the molding 118 surrounding the die 108. The components illustrated in FIG. 5 that are the same as or similar to those of FIG. 1 are given the same reference numbers, except that the conductive underfill of FIG. 5 is given reference number 514.

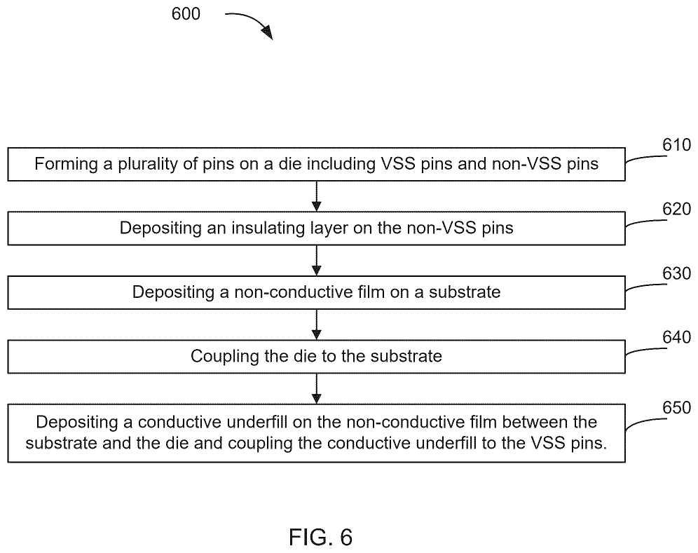

FIG. 6 illustrates a method 600 for manufacturing an IC package (such as the IC package example 100 and/or 500), according to aspects of the disclosure. In some aspects, FIGS. 2A-2D, FIGS. 3A-3E, and FIG. 4 may depict portions of the IC package examples at different stages of manufacturing according to the method 600.

At operation 610, a plurality of pins (e.g., pins 110A, 110B, 110C, 110D, 110E, 110F, 110G, 110H and 110I) may be formed on a die (e.g., die 108) including VSS pins (e.g., VSS pins 110A, 110B, 110C, 110D and 110E) and non-VSS pins (e.g., non-VSS pins 110F, 110G, 110H and 110I). In some aspects, the pins may be formed on the die by a standard bumping process as depicted in FIG. 2B, or by a standard bumping process before reflow as depicted in FIG. 3B, or by one or more other processes.

At operation 620, an insulating layer (e.g., insulating layer 112) may be deposited on the non-VSS pins (e.g., non-VSS pins 110F, 110G, 110H and 110I). In an aspect, the insulating layer (e.g., insulating layer 112) may be formed on the sidewalls of the non-VSS pins (e.g., non-VSS pins 110F, 110G, 110H and 110I) by a deposition process, for example, a molecular vapor deposition (MVD) process. In an aspect, the insulating layer (e.g., insulating layer 112) may comprise SiO₂. In some aspects, the insulating layer (e.g., insulating layer 112) may comprise an insulator material such as . . . .

At operation 630, a non-conductive film (e.g., non-conductive film 104) may be deposited on a substrate (e.g., substrate 102). In an aspect, the non-conductive film (e.g., non-conductive film 104) may be disposed on a first surface (e.g., first surface 106) of the substrate (e.g., substrate 102).

At operation 640, the die (e.g., die 108) may be coupled to the substrate (e.g., substrate 102). At operation 650, a conductive underfill (e.g., conductive underfill 114) may be deposited on the non-conductive film (e.g., non-conductive film 104) between the substrate (e.g., substrate 102) and the die (e.g., die 108), and the conductive underfill (e.g., conductive underfill 114) may be coupled to the VSS pins (e.g., VSS pins 110A, 110B, 110C, 110D and 110E).

The method 600 may include additional implementations, such as any single implementation or any combination of implementations described below and/or in connection with one or more other processes described elsewhere herein.

In some aspects, the method 600 may include pre-treating (e.g., baking, plasma treatment, and/or other processes) the substrate (e.g., substrate 102).

In some aspects, the method 600 may include encapsulating the die (e.g., die 108) in a mold compound.

In some aspects, the conductive underfill (e.g., conductive underfill 114) may comprise a conductive paste.

In some aspects, depositing the insulating layer (e.g., insulating layer 112) may include depositing a molecular vapor deposition (MVD) layer on one or more sidewalls of one or more of the non-VSS pins (e.g., non-VSS pins 110F, 110G, 110H and 110I).

In some aspects, the MVD layer may comprise silicon dioxide (SiO₂).

Although FIG. 6 shows example operations of the method 600, in some implementations, the method 600 may include additional blocks, fewer blocks, different blocks, or differently arranged blocks than those depicted in FIG. 6. Additionally, or alternatively, two or more operations of the method 600 may be performed in parallel, or may be performed in a temporal sequence other than the sequence listed in FIG. 6.

A technical advantage of the method 600 corresponds to manufacturing an integrated circuit (IC) package that includes a conductive underfill coupled to the VSS pins of the IC die while the non-VSS pins are electrically insulated from the conductive underfill by an insulating layer. In some aspects, by providing robust electrical connections between the VSS pins while electrically insulating the non-VSS pins from the VSS pins in an IC package in which the pins may be densely positioned relative to each other, a high level of system performance may be achieved by providing improved I/O return paths.

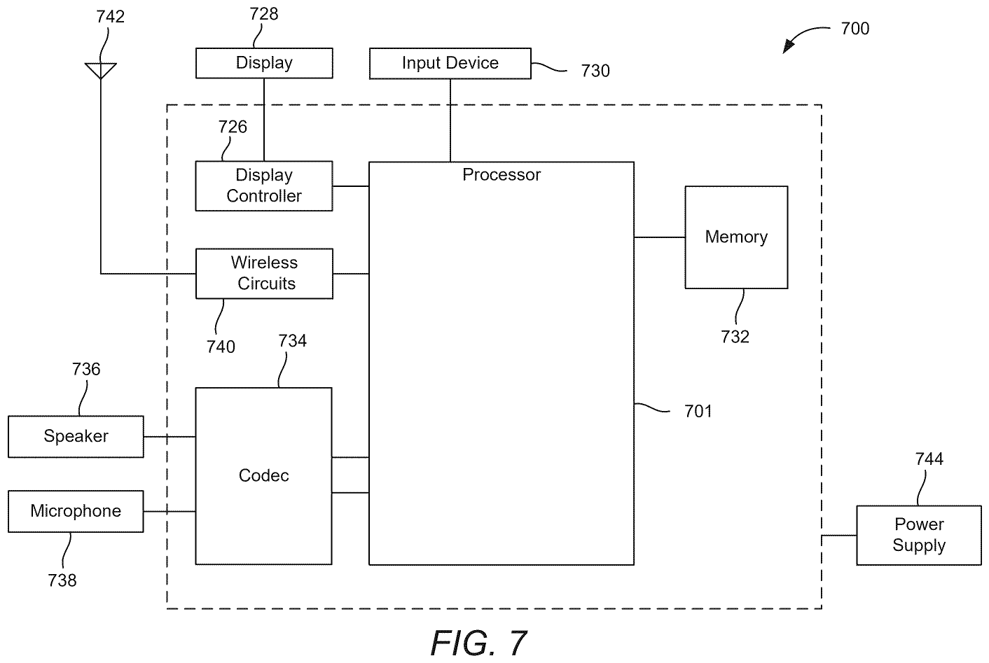

FIG. 7 illustrates a mobile device 700, according to aspects of the disclosure. In some aspects, the mobile device 700 may be implemented by including a IC device that is implemented based on the IC package disclosed herein.

In some aspects, mobile device 700 may be configured as a wireless communication device. As shown, mobile device 700 includes processor 701. Processor 701 may be communicatively coupled to memory 732 over a link, which may be a die-to-die or chip-to-chip link. Mobile device 700 also includes display 728 and display controller 726, with display controller 726 coupled to processor 701 and to display 728. The mobile device 700 may include input device 730 (e.g., physical, or virtual keyboard), power supply 744 (e.g., battery), speaker 736, microphone 738, and wireless antenna 742. In some aspects, the power supply 744 may directly or indirectly provide the supply voltage for operating some or all of the components of the mobile device 700.

In some aspects, FIG. 7 may include coder/decoder (CODEC) 734 (e.g., an audio and/or voice CODEC) coupled to processor 701; speaker 736 and microphone 738 coupled to CODEC 734; and wireless circuits 740 (which may include a modem, RF circuitry, filters, etc.) coupled to wireless antenna 742 and to processor 701.

In some aspects, one or more of processor 701 (e.g., SoCs, application processor (AP)), display controller 726, memory 732, CODEC 734, and wireless circuits 740 (e.g., baseband interface) including IC devices that are packaged as IC packages according to the various aspects described in this disclosure.

It should be noted that although FIG. 7 depicts a mobile device 700, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

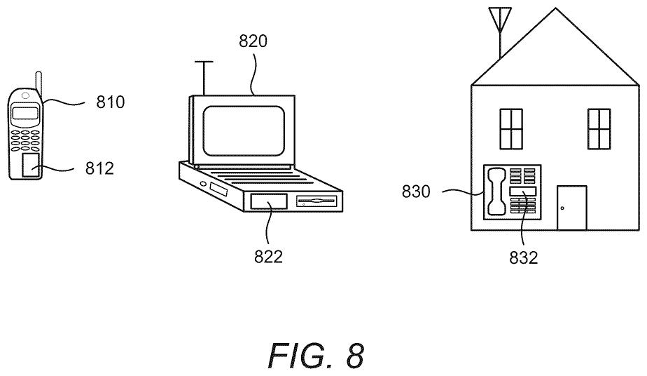

FIG. 8 illustrates various electronic devices 810, 820, and 830 that may incorporate IC devices 812, 822, and 832, which may be packaged as IC packages described herein, according to aspects of the disclosure.

For example, a mobile phone device 810, a laptop computer device 820, and a fixed location terminal device 830 may each be considered generally user equipment (UE) and may include one or more IC devices, such as IC devices 812, 822, and 832, and a power supply to provide the supply voltages to power the IC devices. The IC devices 812, 822, and 832 may be, for example, correspond to an IC device packaged as an IC package having a package substrate manufactured based on the examples described above with reference to FIGS. 1-6.

The devices 810, 820, and 830 illustrated in FIG. 8 are merely non-limiting examples. Other electronic devices may also feature the IC devices including package substrates as described in this disclosure, including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device, an access point, a base station, or any other device that stores or retrieves data or computer instructions or any combination thereof.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1-8 may be rearranged and/or combined into a single component, process, feature, or function or incorporated in several components, processes, or functions. Additional elements, components, processes, and/or functions may also be added without departing from the disclosure. In some implementations, FIGS. 1-8 and the corresponding description may be used to manufacture, create, provide, and/or produce integrated devices. In some implementations, a device may include a die, an integrated device, a die package, an IC, a device package, an IC package, a wafer, a semiconductor device, a system in package (SiP), a system on chip (SoC), a package on package (POP) device, and the like.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. A device, comprising: a substrate having a non-conductive film disposed on a first surface; a die having a plurality of pins including VSS pins and non-VSS pins having an insulating layer, wherein the plurality of pins are coupled to the substrate through the non-conductive film; and a conductive underfill disposed between the die and the substrate, wherein the conductive underfill is coupled to the VSS pins.

Clause 2. The device of clause 1, wherein the non-conductive film is separated from the die by a gap.

Clause 3. The device of clause 2, wherein the gap between the non-conductive film and the die is occupied by the conductive underfill.

Clause 4. The device of any of clauses 1 to 3, wherein the conductive underfill comprises a conductive paste.

Clause 5. The device of any of clauses 1 to 4, wherein the insulating layer is disposed between the non-VSS pins and the conductive underfill.

Clause 6. The device of clause 5, wherein the insulating layer comprises silicon dioxide (SiO2).

Clause 7. The device of any of clauses 1 to 6, wherein the substrate comprises a VSS plane configured to operate at a ground or negative potential.

Clause 8. The device of any of clauses 1 to 7, wherein the substrate comprises a VDD plane configured to operate at a ground or positive potential.

Clause 9. A method of making a device, comprising: forming a plurality of pins on a die including VSS pins and non-VSS pins; depositing an insulating layer on the non-VSS pins; depositing a non-conductive film on a substrate; coupling the die to the substrate; and depositing a conductive underfill on the non-conductive film between the substrate and the die and coupling the conductive underfill to the VSS pins.

Clause 10. The method of clause 9, further comprising pre-treating the substrate.

Clause 11. The method of any of clauses 9 to 10, further comprising encapsulating the die in a mold compound.

Clause 12. The method of any of clauses 9 to 11, wherein the conductive underfill comprises a conductive paste.

Clause 13. The method of any of clauses 9 to 12, wherein depositing the insulating layer comprises: depositing a molecular vapor deposition (MVD) layer on sidewalls of the non-VSS pins.

Clause 14. The method of clause 13, wherein the MVD layer comprises silicon dioxide (SiO2).

Clause 15. An electronic device, comprising: an integrated circuit (IC) package that comprises: a substrate having a non-conductive film disposed on a first surface; a die having a plurality of pins including VSS pins and non-VSS pins having an insulating layer, wherein the plurality of pins are coupled to the substrate through the non-conductive film; and a conductive underfill disposed between the die and the substrate, wherein the conductive underfill is coupled to the VSS pins.

Clause 16. The electronic device of clause 15, wherein the non-conductive film is separated from the die by a gap.

Clause 17. The electronic device of clause 16, wherein the gap between the non-conductive film and the die is occupied by the conductive underfill.

Clause 18. The electronic device of any of clauses 15 to 17, wherein the conductive underfill comprises a conductive paste.

Clause 19. The electronic device of any of clauses 15 to 18, wherein the insulating layer is disposed between the non-VSS pins and the conductive underfill.

Clause 20. The electronic device of any of clauses 15 to 19, wherein the electronic device comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such. Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

What is claimed is:

1. A device, comprising:
a substrate having a non-conductive film disposed on a first surface;
a die having a plurality of pins including VSS pins and non-VSS pins having an insulating layer, wherein the plurality of pins are coupled to the substrate through the non-conductive film; and
a conductive underfill disposed between the die and the substrate, wherein the conductive underfill is coupled to the VSS pins.

2. The device of claim 1, wherein the non-conductive film is separated from the die by a gap.

3. The device of claim 2, wherein the gap between the non-conductive film and the die is occupied by the conductive underfill.

4. The device of claim 1, wherein the conductive underfill comprises a conductive paste.

5. The device of claim 1, wherein the insulating layer is disposed between the non-VSS pins and the conductive underfill.

6. The device of claim 5, wherein the insulating layer comprises silicon dioxide (SiO₂).

7. The device of claim 1, wherein the substrate comprises a VSS plane configured to operate at a ground or negative potential.

8. The device of claim 1, wherein the substrate comprises a VDD plane configured to operate at a ground or positive potential.

9. A method of making a device, comprising:
forming a plurality of pins on a die including VSS pins and non-VSS pins;
depositing an insulating layer on the non-VSS pins;
depositing a non-conductive film on a substrate;
coupling the die to the substrate; and
depositing a conductive underfill on the non-conductive film between the substrate and the die and coupling the conductive underfill to the VSS pins.

10. The method of claim 9, further comprising pre-treating the substrate.

11. The method of claim 9, further comprising encapsulating the die in a mold compound.

12. The method of claim 9, wherein the conductive underfill comprises a conductive paste.

13. The method of claim 9, wherein depositing the insulating layer comprises:
depositing a molecular vapor deposition (MVD) layer on sidewalls of the non-VSS pins.

14. The method of claim 13, wherein the MVD layer comprises silicon dioxide (SiO₂).

15. An electronic device, comprising:
an integrated circuit (IC) package that comprises:
a substrate having a non-conductive film disposed on a first surface;
a die having a plurality of pins including VSS pins and non-VSS pins having an insulating layer, wherein the plurality of pins are coupled to the substrate through the non-conductive film; and
a conductive underfill disposed between the die and the substrate, wherein the conductive underfill is coupled to the VSS pins.

16. The electronic device of claim 15, wherein the non-conductive film is separated from the die by a gap.

17. The electronic device of claim 16, wherein the gap between the non-conductive film and the die is occupied by the conductive underfill.

18. The electronic device of claim 15, wherein the conductive underfill comprises a conductive paste.

19. The electronic device of claim 15, wherein the insulating layer is disposed between the non-VSS pins and the conductive underfill.

20. The electronic device of claim 15, wherein the electronic device comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.
